(19) United States
(12) Patent Application Publication
(10) Pub. No.: US 2007/0044835 A1
(43) Pub. Date: Mar. 1, 2007

(54) Semiconductor electrode, dye sensitized solar cells and manufacturing method of the same

(76) Inventors: Naoki Yoshimoto, Hitachi (JP); Takeyuki Itabashi, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/511,294

(22) Filed: Aug. 29, 2006

(30) Foreign Application Priority Data
Aug. 29, 2005 (JP) 2005-246982

(51) Int. Cl. H01L 31/00

(52) U.S. Cl. 136/263

(57) ABSTRACT

A semiconductor electrode comprises a substrate having optical transparency, a transparent conductive layer provided on a photo-receptive surface of the substrate, and a porous semiconductor made of a metal oxide provided on the transparent conductive layer. The porous semiconductor has at least dye and a thiophene-ring-containing organic compound adsorbed thereon.

### CLAIM OF PRIORITY

The present application claims priority from Japanese application serial No. 2005-246982, filed on Aug. 29, 2005, the content of which is hereby incorporated by reference into this application.

### FIELD OF THE INVENTION

The present invention relates to dye sensitized solar cells, a semiconductor electrode used for the same, and a manufacturing method of the same.

### BACKGROUND OF THE INVENTION

In recent years, global warning caused by carbon dioxide has become a serious increased concern, and fossil fuel substitutes have attracted keen interest from persons. Accordingly, reduction of carbon dioxide emissions or a cogeneration system for making effective use of heat generated when electricity is generated has attracted attention. In particular, photovoltaic power generation making effective use of natural energy has been attracting much attention as an energy system which does not depend on fossil fuels. Among solar cells, dye sensitized solar cells have been studied briskly for their industrialization since they were reported by Professor Graetzel, et al. because of a low cost of raw materials and convenience of fabrication process which does not require a vacuum apparatus.

The main problems of dye sensitized solar cells to be solved are improvement of photovoltaic conversion efficiency (characteristic of cell) and elongation of cell life to a practical level. In short, dye sensitized solar cells must maintain a high photovoltaic conversion efficiency even if they are driven or in storage for a long time.

In dye sensitized solar cells, a semiconductor electrode as a photoelectrode having a light absorbing function (photosensitization) is manufactured by process in which a sensitizing dye is adsorbed on a porous metal oxide-semiconductor electrode. Accordingly, it is presumed to be important to enlarge the surface area of the electrode by rendering the metal oxide semiconductor porous and thereby enabling a greater amount of the dye adsorption.

It is however difficult to completely adsorb the dye on the surface of the semiconductor electrode to coat the surface therewith because pores of the porous are smaller than the molecules of the dye or because a dye solution does not readily penetrate into the pores due to intricate structure of the pores. Therefore, uncoated portions missing dye adsorption usually remain in the semiconductor electrode surface.

It is known that when the uncoated semiconductor electrode is brought into direct contact with an electrolyte (for example, an electrolyte solution dissolved in an organic solvent) containing a redox couple composed of I³⁻/I⁻, “reverse electron transfer” in which electrons are directly injected into an electrolyte solution from the semiconductor electrode occurs and this reduces an open circuit voltage of a cell module (refer to, for example, Japanese Patent Application Laid-Open No. 2001-52766).

Moreover, such “reverse electron transfer” results problems such as reduction in output power and output photocurrent density of the cell module. It is known to add an organic compound into the electrolyte for the purpose of preventing the above-described “reverse electron transfer”.

As the organic compound to be added into the electrolyte, a base consisting of a nitrogen-containing cyclic compound such as 4-tert-butylpyridine or N-methylbenzimidazole is known (refer to Mohammad K. et al., Journal of American Chemical Society, 123, 1613-1624(2001)). It is presumed that such a base compound coordinates on the surface of the metal oxide semiconductor by means of a nitrogen atom and thereby has an effect of coating therewith the surface. By the addition of the base compound, an open circuit voltage of the cell module cells) is presumed to become greater than that when it is not added.

Since the nitrogen atom of the base compound has an unshared electron pair, a phenomenon (donation) in which electrons are apparently pushed toward the metal oxide is said to occur. This effect is known to increase the photocurrent density and output power of dye sensitized solar cells (refer to Kusama H. et al., Journal of Photochemistry and Photobiology A: Chemistry, 164, 103-110(2004)).

In addition to the above-described compounds, pyrimidine derivatives and triazole derivatives are known as the base compound having such effects. Pyrimidine and triazole are considered to be advantageous over 4-tert-butylpyridine and N-methyl benzimidazole from the viewpoint of driving or storage of dye sensitized solar cells for a long time because they have weaker base strength (strength of an organic compound as a base) than the above-described base compound (refer to, for example, Japanese Patent Application Laid-Open No. 2004-247158).

The reason why the nitrogen-containing cyclic organic compound can prevent a reduction in the open circuit voltage has not yet been completely elucidated. The inventors of this patent application have considered that the base compound added into the electrolyte adsorbs on the metal oxide not coated with the dye and prevents a direct contact of the metal oxide with the electrolyte. The inventors have however found that dye sensitized solar cells having electrolytes added with a base made of a nitrogen-containing cyclic compound such as 4-tert-butylpyridine or N-methylbenzimidazole can not have sufficient stability in continuous driving. Because a marked decay of photocurrent occurs when the cells are driven for a long time. They have also found that a time-dependent reduction of photovoltaic conversion efficiency occurs even in the solar cells stored for a long time in a dark place so that the cells are also insufficient in storage stability.

The present invention is to provide excellent durability-dye sensitized solar cells having a high photovoltaic conversion efficiency in the early stage after manufacturing the cells and which can have a sufficient photovoltaic conversion efficiency even if driven for a long time or driven after long term storage.

### SUMMARY OF THE INVENTION

The inventors have carried out an intensive investigation with a view to attaining the above-described object. As a result, it has been found that in a dye sensitized solar cell having an electrolyte added with a base made of a nitrogen-containing cyclic compound such as 4-tert-butylpyridine or N-methylbenzimidazole, the dye which has adsorbed on-the surface of the metal oxide is desorbed by the base; and deterioration in the dye which has adsorbed on the metal oxide surface of the electrode or the dye which has been desorbed from the electrode surface and existing in the electrolyte is caused by the base. The inventors have come to the conclusion that a main cause of a marked deterioration in the characteristics of the dye sensitized solar cells are desorption or deterioration of the dye.

The inventors have carried out a further investigation. As a result, it has been found that the base causative of desorption or deterioration of the dye is a base existing in the electrolyte so the problem can be overcome by minimizing the concentration of the base in the electrolyte and replacing the base made of a nitrogen-containing cyclic compound such as 4-tert-butylpyridine or N-methylbenzimidazole with a thiophene-ring-containing organic compound.

Described specifically, it has been found that “reverse electron transfer” can be prevented sufficiently by bringing a thiophene-ring-containing organic compound into adsorption on the semiconductor electrode made of a metal oxide where the dye is adsorbed and by coating dye adsorption-missing portions, which are in direct contact with the electrolyte in the surface of the electrode, with the thiophene-ring-containing organic compound. It has also been found that since such a thiophene-ring-containing organic compound has higher adsorptivity to the surface of the semiconductor electrode than a heterocyclic compound, it has an effect of not causing deterioration of the photovoltaic conversion efficiency of dye sensitized solar cells even if the cells are driven for a long time or driven after long term storage.

The present invention provides a semiconductor electrode comprising a substrate having optical transparency, a transparent conductive layer provided on a photo-receptive surface of the substrate, and a porous semiconductor made of a metal oxide provided on the transparent conductive layer, wherein the porous semiconductor has a dye and a thiophene-ring-containing organic compound adsorbed thereon. The present invention furthermore provides a dye sensitized solar cell comprising the above-mentioned semiconductor electrode, a counter electrode thereof, and an electrolyte interposed between the semiconductor electrode and the counter electrode.

The present invention makes it possible to easily construct a dye sensitized solar cell capable of providing a high photovoltaic conversion efficiency in the early stage after manufacturing and moreover, and capable of enough keeping a sufficient photovoltaic conversion efficiency even if the cell module as cells is driven for a long time or driven after long term storage, by adsorbing a thiophene-ring-containing compound a porous semiconductor made of a metal oxide into which a dye has been adsorbed, instead of a nitrogen-containing cyclic compound such as 4-tert-butylpyridine or N-methylbenzimidazole.

The reason why adsorption of a thiophene-ring-containing organic compound onto a porous metal oxide-semiconductor electrode with a dye adsorption can prevent desorption of the dye adsorbed on the metal oxide surface and can prevent deterioration of the dye has not yet been made clear. About the reason, the inventors have considered that, when a base is contained in an electrolyte, reaction or exchange adsorption between the base and metal oxide occurs on the metal oxide surface with a high acidity, resulting in desorption of the dye. In practice, when a semiconductor electrode having a dye adsorbed thereto is dipped in a strongly basic liquid such as an aqueous solution of sodium hydroxide, the dye is desorbed from the surface of the semiconductor electrode almost completely.

The inventors have considered that, regarding the base consisting of a nitrogen-containing cyclic compound added to an electrolyte of the conventional dye sensitized solar cell, the site of the nitrogen atom of the base reacts with the coordination center of ruthenium ion (or ruthenium atom) and the like of a dye (for example, organic metal complex such as ruthenium complex) in a porous semiconductor electrode and thereby promotes the desorption reaction of the original ligand.

It is also known that a strongly basic compound reacts with a redox pair of iodine. So the inventors consider that there may be a possibility of the above-described base consisting of a heterocyclic compound decreasing the concentration of the redox pair of iodine in the electrolyte.

The inventors have found that even a dye sensitized solar cell comprising an electrolyte added with a weakly basic pyrimidine derivative or triazole derivative can improve a reduction in photocurrent density in the early stage, but a marked decrease in the photocurrent density compared with that in the early stage occurs when the cell is driven for a long time or driven after long term storage.

In the present invention, a thiophene-ring-containing organic compound is adsorbed to a semiconductor electrode. Thereby, desorption of the dye which has occurred in the conventional technology can be minimized. In the conventional technology of incorporating the organic compound into the electrolyte, exchange adsorption reaction occurs between the dye and the organic compound incorporated in the electrolyte, whereby desorption of the dye is promoted by the action of the nitrogen-containing organic compound.

A thiophene-containing organic compound adsorbs strongly to the surface of a semiconductor electrode. The inventors consider that this enables to prevent desorption of adsorbed molecules as compared to the nitrogen-containing organic compound, and the thiophene-containing organic compound is more effective for coating the surface of the semiconductor electrode and for preventing desorption of the dye.

In the present invention, the term “dye” means a metal complex dye typified by a ruthenium complex such as cis-di(thiocyanato)-N,N′-bis(2,2′-bipyridyl-4,4′-dicarboxylic acid)-Ruthenium (II) or an organic dye typified by coumarin or cyanine. The term “electrolyte” means (i) solution of electrolyte (which will hereinafter be called “electrolyte solution”), (ii) electrolyte in the gel form obtained by adding a gelling agent to an electrolyte solution, (iii) solid electrolyte, or (iv) porous material having, in the pores thereof, any one of the above-described electrolytes (i) to (iii) contained.

The present invention makes it possible to provide a dye sensitized solar cell (cells) capable of providing a high photoelectric (photocurrent) conversion efficiency in the early stage, and moreover, capable of keeping sufficient photovoltaic conversion characteristics even when driven for a long time or driven after long term storage and therefore having excellent durability.

### BRIEF DESCRIPTION OF THE DRAWINGS

FIG. 1 is a schematic cross-sectional view illustrating a semiconductor electrode constituting the dye sensitized solar cell of the present invention.

FIG. 2 is a schematic cross-sectional view illustrating the principal constitution of a first embodiment of the present invention.

FIG. 3 is a schematic cross-sectional view illustrating the principal constitution of a second embodiment of the present invention.

FIG. 4 is a graph showing a time-dependent change of a short-circuit current density of each of the dye sensitized solar cells obtained in Example 1 and Comparative Example 3.

### DETAILED DESCRIPTION OF THE PREFERRED EMBODIMENTS

The best mode of a porous semiconductor electrode and a dye sensitized solar cell according to the present invention will hereinafter be described in detail referring to accompanying drawings. In the below description, members having like function will be identified by like reference numerals and overlapping descriptions will be omitted.

### First Embodiment

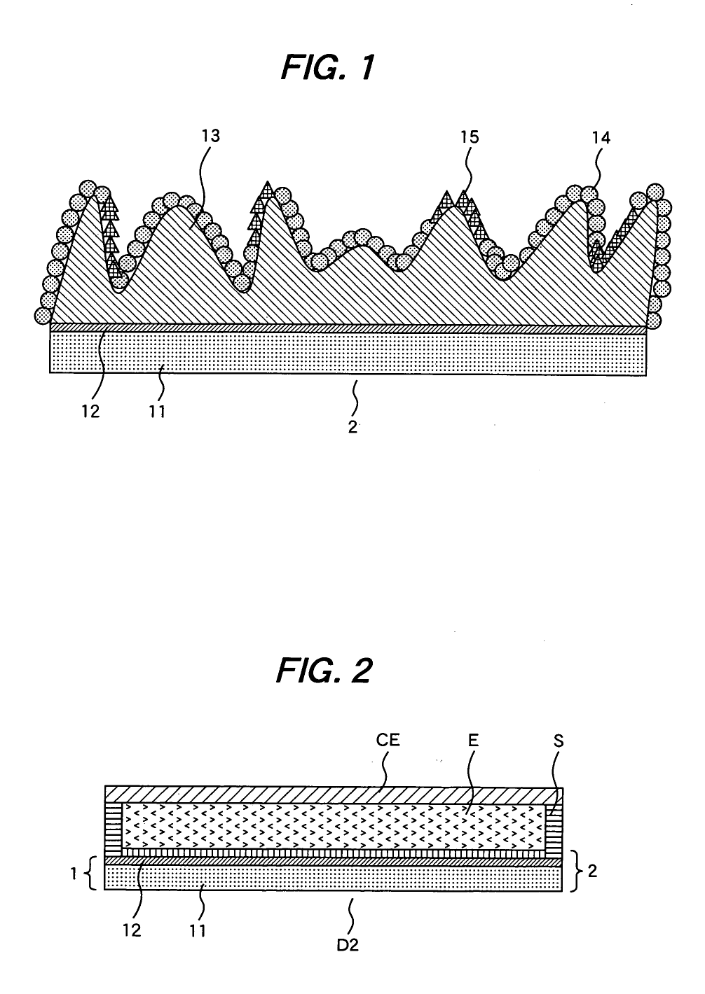

FIG. 1 is a schematic cross-sectional view illustrating the essential structure of a semiconductor electrode of the present invention.

A semiconductor electrode 2 as illustrated in FIG. 1 comprises a transparent electrode composed mainly of a transparent substrate 11 and a transparent conductive layer 12 provided onto the substrate 11. A porous semiconductor 13 made of a metal oxide is provided onto the transparent conductive layer 12 in contact with the layer 12. A dye 14 and a thiophene-ring-containing organic compound 15 are adsorbed onto the semiconductor 13 and they constitute an electrode (photoelectrode) capable of absorbing light.

No limitation is imposed on the material of the substrate 11 insofar as it has optical transparency. Glasses such as soda glass or flexible materials typified by a transparent resin such as polyethylene terephthalate may be employed.

No particular limitation is imposed on the constitution of the transparent conductive layer 12, and a transparent electrode to be mounted on ordinary dye sensitized solar cells can be utilized as the layer 12. Examples of this transparent electrode include fluorine-doped tin oxide (FTO), indium-doped tin oxide (ITO), Al-coated zinc oxide glass (AZO) and antimony-doped tin oxide (ATO). Such transparent electrodes made of a metal oxide may be used either singly or stacked one after another. The conductivity of these metal oxides may be increased by doping a cation or anion different in valency.

The metal oxide-porous semiconductor 13 as illustrated in FIG. 1 is made of an oxide semiconductor layer using metal oxide-fine particles. No particular limitation is imposed on the metal-oxide fine particles to be included in the semiconductor electrode 2 and known metal oxide semiconductor can be utilized. Examples of the oxide semiconductor include TiO₂, ZnO, SnO₂, Nb₂O₅, In₂O₃, WO₃, ZrO₂, La₂O₃, Ta₂O₅, SrTiO₃ and BaTiO₃. Of these oxide semiconductors, anatase TiO₂ is preferred.

The sensitizing dye 14 is supported by the porous semiconductor 13. No particular limitation is imposed on the dye 14 of FIG. 1, insofar as it is a dye having absorption in a visible light region and(or) infrared light region. It is more preferably a dye to be excited by light having at least a wavelength of 200 nm to 2 μm. Metal complexes and organic dyes can be used as such a sensitized dye.

Examples of the metal complex include metal phthalocyanines such as copper phthalocyanine and titanyl phthalocyanine, chlorophyll or derivatives thereof, and complexes of hemin, ruthenium, osmium, iron or zinc (such as cis-Di(thiocyanato)-N,N′-bis(2,2′-bipyridyl-4,4′-dicarboxylic acid)-Ruthenium (II). Examples of the organic dye include metal-free phthalocyanine, cyanine dyes, merocyanine dyes, xanthene dyes, triphenylmethane dyes and coumarin dyes.

Although no particular limitation is imposed on the supporting method of the sensitizing dye 14 in FIG. 1, it is usually performed by dipping the semiconductor electrode 2 with the metal oxide semiconductor 13 and the transparent conductive layer 12 in an alcohol solution having the dye dissolved therein. It is possible to shorten time required for supporting the dye by dipping the substrate while heating or refluxing the dye solution.

No particular limitation is imposed on the organic compound 15 supported by the metal oxide porous semiconductor electrode as illustrated in FIG. 1 insofar as it has a thiophene ring. The organic compound 15 is adsorbed onto dye missing portions (which are portions without dye coating and where the metal oxide of the semiconductor 13 is exposed) in the surface of the porous semiconductor 13 so as to coated the dye missing portions to prevent “reverse electron transfer” from the metal oxide to the electrolyte.

It is desired that in order to surely obtain the advantage of the present invention from the viewpoint of preventing the “reverse electron transfer”, the thiophene-ring-containing organic compound has, as the skeleton thereof, a structure represented by the following formula (1):

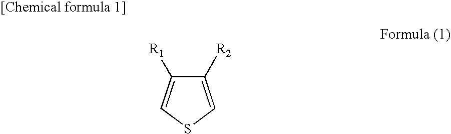

In the formula (1), R₁ and R₂ may be the same or different and each represents a characteristic group selected from the class consisting of a hydrogen atom, hydrocarbon groups having from 1 to 20 carbon atoms, and alkoxy groups having from 1 to 20 carbon atoms. More preferably, an alkoxy-containing organic compound having a structure as illustrated in the formula (2) such as ethylenedioxythiophene is selected.

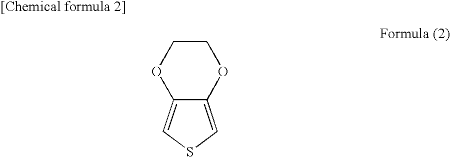

It is not obvious why the organic compound having, on the thiophene ring thereof, an alkoxy group as illustrated in the formula (2) is preferred, but owing to an increased electron acceptance of the thiophene ring due to the alkoxy group, the resulting organic compound easily adsorbs onto the surface of the metal oxide-semiconductor electrode. In addition to the compound of the formula (2), organic compounds represented by the formulas (3) to (5) can be given as examples of the thiophene-ring-containing organic compound. These organic compounds may be used either singly or in combination.

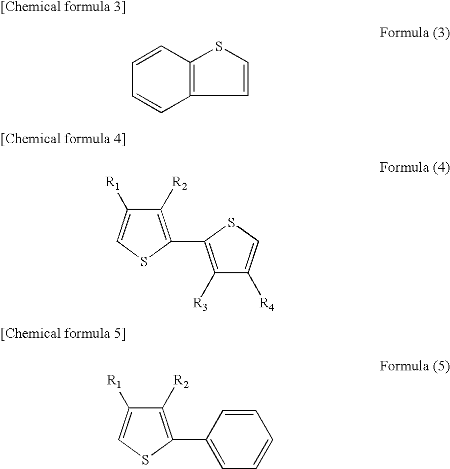

The thiophene-ring-containing organic compound is adsorbed onto no dye supported portion (dye adsorption-missing portion) of the semiconductor 13. Thereby, “reverse electron transfer” is not only suppressed but also apparent electron donation to the semiconductor electrode from the organic compound 15 is presumed to occur because the compound has a sulfur atom. This donation is presumed to contribute to an increase of photoelectric current.

Although no particular limitation is imposed on the supporting method of the thiophene-ring-containing organic compound 15 on the substrate, it is preferably performed by dipping the substrate with the dye 14 supported thereon into a solution having the thiophene-ring-containing compound dissolved therein. When the thiophene-ring-containing organic compound 15 is in the liquid form, the substrate may be directly dipped in the organic compound or the organic compound may be applied to the substrate. The thiophene-ring-containing organic compound may be adsorbed to the semiconductor electrode by allowing it to stand in a container filled with the vapor of the organic compound.

No particular limitation is imposed on the concentration of a solution of the thiophene-ring-containing organic compound 15, but it is preferably from 0.01 to 1 mol/l. When the concentration is below the above-described range, the organic compound 15 cannot be supported by the substrate efficiently even by dipping and moreover, peeling of the dye may occur. When the concentration exceeds the above-described range, the supporting of the organic compound occurs in priority and exchange reaction with the dye which has already been adsorbed may occur.

No particular limitation is imposed on the organic solvent for dissolving the thiophene-ring-containing organic compound 15 therein, but a solvent in which the dye 14 is sparingly soluble or insoluble is preferred. For example, acetonitrile is a low-boiling-point solvent in which the dye is sparingly soluble. When the substrate is allowed to stand for a while in the air after dipping, the solvent can be removed by natural drying.

The optimum dipping time for supporting the thiophene-ring-containing organic compound 15 on the semiconductor electrode with the adsorbed dye, namely the optimum dipping time of the substrate with the semiconductor electrode in a solution of the organic compound, is varied depending on the concentration of the solution of the thiophene-ring-containing organic compound. The dipping time is preferably for from about 10 seconds to 2 hours when the concentration of the solution is from 0.01 to 1 mol/l. When the dipping time is below this range, the thiophene-ring-containing organic compound hardly is adsorbed onto the semiconductor electrode with the adsorbed dye. When the dipping time exceeds 2 hours, on the other hand, exchange reaction of adsorption between the dye and organic compound occurs.

The thiophene-ring-containing organic compound 015 is provided for the purpose of coating onto portions of the surface of the semiconductor 13, namely the dye adsorption-missing portions where the dye can not be coated in the surface of the semiconductor 13 (the portions in which the semiconductor itself is exposed). To satisfy this purpose, the amount of the dye supported on the semiconductor is preferably as much as possible. In the substrate 11 having the semiconductor 13 and transparent conductive layer 12, it is therefore preferred to support the maximum possible amount of the dye 14 on the semiconductor by the above-described treatment and then support the thiophene-ring-containing organic compound 15.

The thiophene-ring-containing organic compound 15 is preferably coated only the portions where the dye can not be coated in the surface of the semiconductor electrode 2, in other words, portions from which the semiconductor electrode itself is exposed. More preferably, the portions are coated with a monomolecular layer of the thiophene-ring-containing organic compound. In order to satisfy such a condition, the organic compound 15 has preferably a molecular weight of 8000 or less. The organic compound having a molecular weight exceeding 8000 cannot easily be adsorbed selectively to the exposed portion of the semiconductor electrode itself and it is likely to coat even the dye adsorbed on the semiconductor electrode. If organic compound 15 has coated even the dye, it is not preferred. Because it hinders the reaction between the dye and the redox pair of the electrolyte solution and becomes a cause of decomposition or deterioration of the dye.

The thiophene-ring-containing organic compound 15 preferably has been adsorbed onto the inside surface of the pores at the portions which has not been coated with the dye in the porous semiconductor electrode. Accordingly, it is usually preferred that each of R₁ and R₂ in the formula (1) is a characteristic group having less steric bulkiness in order to facilitate penetration of the organic compound 15 into the pores. A characteristic group having a bulky skeleton is not suited.

The structure of a dye sensitized solar cell using the porous semiconductor electrode 2 as illustrated in FIG. 1 will next be described. FIG. 2 is a schematic cross-sectional view of the dye sensitized solar cell D2 using the porous semiconductor electrode.

The dye sensitized solar cell as illustrated in FIG. 2 is composed of the porous semiconductor electrode 2 as described above, a counter electrode CE, a spacer S, and an electrolyte E filling a space surrounded by the porous semiconductor electrode 2, counter electrode E and spacer S.

No particular limitation is imposed on the material of the counter electrode CE insofar as it can deliver electrons to the redox pair (I₃⁻/I⁻) in the electrolyte (electrolyte solution E) with high efficiency. The counter electrode may have a similar structure to that of the transparent electrode 1, or it may be similar to the transparent electrode 1 except that a metal thin-layer electrode made of, for example, Pt is formed on the transparent conductive layer 12 by sputtering and then the metal thin-layer electrode is disposed to face to the electrolyte solution E. A layer formed on the transparent conductive layer 12 may be a layer facilitating smooth redox of the electrolyte solution so that the thin layer made of Pt may be replaced by a conductive layer made of, for example, carbon.

No particular limitation is imposed on the electrolyte insofar as it contains at least a redox pair including iodine. This electrolyte may be either in the solution form obtained by dissolving it in an organic solvent or may be in the gel form available by adding a known gelling agent to the electrolyte solution. The electrolyte E is filled even in the pore portions of the porous semiconductor electrode of FIG. 1. When the counter electrode CE is made of a porous electron conductive material, the electrolyte E is filled also in the pore portions inside of this counter electrode CE.

The electrolyte E may contain an imidazolium salt having an iodine ion as a counter ion to smoothly diffuse the redox pair in the electrolyte. Examples of the imidazolium salt include 2,3-dimethyl-imidazolium iodine.

No particular limitation is imposed on the solvent to be used for the electrolyte E insofar as it can dissolve a solute component therein. Solvents which are electrochemically inert, have a high dielectric constant and have low viscosity (or mixed solvent of them) are preferred. Examples include nitrile compounds such as methoxyacetonitrile, methoxypropionitrile and acetonitrile, lactone compounds such as γ-butyrolactone and valerolactone, and carbonate compounds such as ethylene carbonate and propylene carbonate.

According to the present invention, the electrolyte E preferably does not contain a base such as 4-tert-butylpyridine. The base not only induces peeling of a dye chemically adsorbed via a carboxylic acid group but also causes decomposition of the ligand of a metal complex such as cis-Di(thiocyanato)-N,N′-bis(2,2′-bipyridyl-4,4′-dicarboxylic acid)-Ruthenium (II).

Moreover, according to the present invention, it is not preferred to prepare the electrolyte E by mixing therein the thiophene-ring-containing organic compound in advance. It has been found that mixing of the thiophene-ring-containing organic compound in the electrolyte E causes an exchange reaction with the dye adsorbed to the semiconductor electrode, leading to the peeling of the dye.

Accordingly, it is most appropriate that the thiophene-ring-containing organic compound coats the portion(s) of the semiconductor to which no dye has been adsorbed and is supported by the semiconductor.

No particular limitation is imposed on the material constituting the spacer S and silica beads and the like can be employed as the material.

A sealant is used for sealing the electrolyte E and integrating the semiconductor electrode 02, counter electrode CE and spacer S into one. Any sealant may be used insofar as it can seal while preventing leakage of the component of the electrolyte E to the outside as much as possible. Examples include epoxy resin, silicone resin, ethylene/methacrylic acid copolymer, and a thermoplastic resin composed of, for example, surface modified polyethylene. In addition, a polyisobutylene thermosetting resin having acrylate or methacrylate at a polymerization site thereof may also be used.

One example of a manufacturing method of the dye sensitized solar cell as illustrated in FIG. 2 will next be described.

The transparent electrode 1 can be manufactured, for example, by using a known process such as spray thermal decomposition in which a precursor of fluorine-doped tin oxide is spray coated to the heated substrate 11 such as glass substrate. As well as the spray thermal decomposition process, known manufacturing techniques of a transparent conductive layer such as vacuum deposition, sputtering, chemical vapor deposition (CVD) and sol-gel process may be employed.

The semiconductor 13 is formed on the transparent conductive layer 12 of the transparent electrode 1, for example, by the following process. First, a dispersion having fine particles of a metal oxide having a predetermined particle size (for example, from about 10 to 30 nm) dispersed therein is prepared. The solvent of this dispersion is not particularly limited insofar as it can disperse therein fine particles of a metal oxide and examples include water, an organic solvent and mixtures thereof. Additives such as surfactant for preventing aggregation of the fine particles of a metal oxide and thickener for regulating the viscosity of the dispersion to facilitate the application of it to the transparent electrode may be added as needed to the dispersion.

The resulting dispersion is then applied onto the transparent conductive layer 12 of the transparent electrode 1, followed by drying. The dispersion can be applied by a bar coating, printing or the like process. After drying, the layer thus formed is heated and baked in the air or in an inert gas atmosphere, whereby a semiconductor electrode is formed. During baking, the surfactant or thickener made of an organic compound is carbonized and evaporated so that the semiconductor 13 can have a porous structure.

A sensitizing dye is then adsorbed onto the surface of the semiconductor 13 in a known manner such as dipping. The sensitizing dye is supported by the semiconductor 13. Adsorption of the sensitizing dye to the semiconductor may be any one of chemical adsorption between the functional group of the sensitizing dye and the surface of the metal oxide, physical adsorption governed by the intramolecular interaction, and deposition on the metal oxide. The sensitizing dye can be adsorbed easily, for example, by dipping an electrode substrate having a metal oxide thereon in a dye solution. The dipping time can be shortened by heating or refluxing of the dye solution.

The thiophene-ring-containing organic compound 015 can be easily adsorbed to the semiconductor electrode 02 having the dye adsorbed thereto by dipping the semiconductor electrode substrate in a solution of the organic compound 15 as in the adsorption of the dye. The thiophene-ring-containing organic compound 15 may be dissolved in the dye solution in advance to cause co-adsorption of the dye and thiophene-ring-containing organic compound to the semiconductor electrode. The thiophene-ring-containing organic compound however sometimes has a greater adsorption rate or adsorption force than that of the dye 14 and in such a case, it adsorbs to the surface of a metal oxide earlier than the dye. The substrate is therefore preferably dipped in the dye solution first and then dipped in the solution of the thiophene-ring-containing organic compound.

The counter electrode CE may be prepared by forming a transparent electrode in a similar manner to that employed for the preparation of the above-described transparent electrode 1 and then depositing a metal such as platinum thereto by sputtering or the like.

The semiconductor electrode 2 and the counter electrode CE thus manufactured may be disposed via the spacer S so that they face to each other at their surfaces having conductivity. The electrolyte E is filled in a space which has been formed between the semiconductor electrode 02 and counter electrode CE by the spacer, whereby the dye sensitized solar cell D2 is completed.

The electrolyte E to be provided to the dye sensitized solar cell may be in the solution form obtained by dissolving the electrolyte E in an organic solvent or in the gel form obtained by adding a gelling agent to the solution of the electrolyte E.

It is also possible that a physical gel made of polysaccharide or a chemically crosslinked gel such as acrylamide is prepared in advance and the resulting gel is dipped in a solution of the electrolyte E to replace the solution in the network structure of the gel with the electrolyte E. The solvent used for the preparation of the gel is preferably the same solvent used for the electrolyte E or a solvent miscible with the solvent of the electrolyte E at a desired ratio. Use of such a solvent enables smooth replacement of the solvent used for the preparation of the gel by the electrolyte solution.

### Second Embodiment

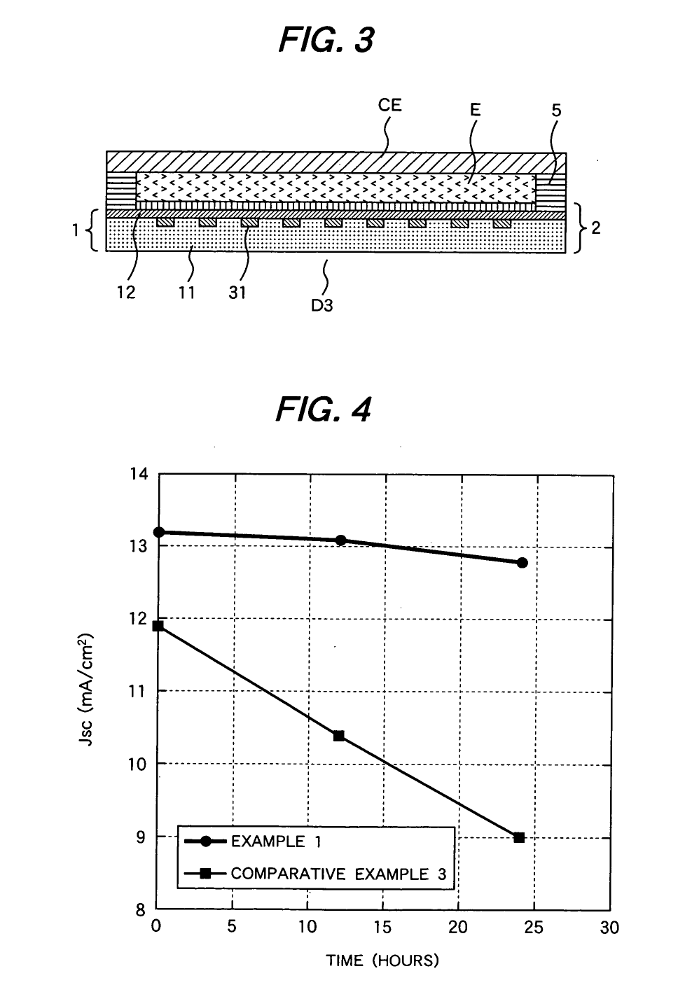

FIG. 3 is a schematic cross-sectional view illustrating the second embodiment of a dye sensitized solar cell of the present invention. Solar cell D3 as illustrated in FIG. 3 will hereinafter be described.

Different from the dye sensitized solar cell D2 as illustrated in FIG. 2, the dye sensitized solar cell D3 as illustrated in FIG. 3 has, in the semiconductor electrode 2 thereof, auxiliary electrode interconnections made of a metal. These auxiliary electrodes are disposed in order to suppress internal resistance derived from the sheet resistance of the transparent conductive layer, which will otherwise increase to a significant level with an increase in the area of the dye sensitized solar cell D3.

No particular limitation is imposed on the material of the auxiliary electrode interconnection 31 in FIG. 3 insofar as it is a low-resistance material such as metal. The metal auxiliary electrode is preferably buried in the substrate 11 to ensure flatness of the substrate.

If the auxiliary electrode interconnection made of a metal is brought into contact with the electrolyte solution E, corrosion of it proceeds, so that it must have a structure capable of avoiding contact with the electrolyte solution. In FIG. 3, the auxiliary electrode interconnection is buried in the substrate 11 and it has a transparent conductive layer formed thereon. Such a structure actualizes electrical contact between the metal auxiliary electrode interconnection and the transparent electrode. The structure furthermore can prevent contact failure, which will otherwise frequently occur by the inclusion of the layer if formation of the interconnection is in the convex form.

By spray pyrolisis deposition (SPD) process or the like similar to that employed for the formation of the transparent electrode 1, a transparent electrode can be formed on such a substrate having auxiliary electrode interconnection made of a metal disposed therein. By this metal auxiliary electrode, photoelectric current can be taken out while maintaining low resistance even if the transparent electrode of the dye sensitized solar cell D3 has an increased area.

This transparent electrode is a layer which serves not only to receive electrons from the semiconductor 13 but also to protect the metal auxiliary electrode interconnection from being brought into contact with the electrolyte E. No particular composition or layer forming method is necessary for the transparent conductive layer 12 to exhibit a function of protecting from the electrolyte. In addition, the anti-corrosive action of the transparent electrode to protect the metal auxiliary electrode from the electrolyte E can easily be actualized by adjusting its layer thickness in a similar manner to that employed for the dye sensitized solar cell D2 of FIG. 2.

The dye sensitized solar cell D3 having a semiconductor electrode equipped with metal auxiliary electrode interconnection and a counter electrode is sealed with a sealant 5 for preventing leakage of the electrolyte E or deterioration due to contact with the air. As the sealant 5, a thermoplastic film such as polyethylene or an epoxy adhesive is usable.

As the sealant 5, a polyisobutylene thermosetting resin can also be employed. Owing to excellent weather resistance and organic solvent resistance, the polyisobutylene resin is suited for sealing of the electrolyte solution.

The dye sensitized solar cells of the present invention will next be described in further detail by Examples and Comparative Examples. It should however be noted that the present invention is not limited to or by these Examples.

### EXAMPLE 1

In accordance with the procedure as described below, the semiconductor substrate 2 as illustrated in FIG. 1 was prepared. First, a semiconductor electrode having a dye adsorbed thereto was prepared. The area of the photo-receptive surface was adjusted to 25 mm². The resulting semiconductor electrode was then dipped in a solution of a thiophene-ring-containing organic compound. The dye sensitized solar cell D2 as illustrated in FIG. 2 was manufactured using this semiconductor electrode.

First, a gel to be a precursor of titanium oxide was prepared in accordance with the process as described in Adachi, et al., Journal of the Electrochemical Society, Volume No.151, 1653-1658(2004). Described specifically, 4.0 g of “Pluronic F127” (trade name; product of BASF), a block copolymer, and 1.5 g of cetyl trimethylammonium bromide were weighed and dissolved in 40 ml of pure water. A mixture of 1.6 g of acetylacetone and 4.5 g of titanium tetraisopropoxide was added dropwise to the resulting solution, followed by vigorous stirring. The reaction mixture was then stirred at 40° C. for 24 hours and allowed to stand at 80° C. for 4 days, whereby Gel 1 was obtained as a precursor of titanium oxide.

Gel 1 was then applied onto a glass substrate having a layer of fluorine-doped tin oxide (product of Nippon Sheet Glass, sheet resistance: about 10 Ω/□) formed thereon by a doctor blade process while using a mending tape as a support. After application, the gel was naturally dried at room temperature and then the gel-applied glass substrate was put into an electric furnace, which had been heated to 450° C., for 10 minutes, whereby the glass substrate was baked. Application of the gel, natural drying and baking were repeated until the layer thickness of titanium oxide reached about 10 μm. The final baking was performed by putting the substrate for 1 hour in the electric furnace heated to 450° C.

A dye was adsorbed to the resulting thin layer of titanium oxide in the following manner. First, a solution of the dye was prepared by dissolving, in ethanol, a sensitizing dye “N719” (trade name; product of Solaronix), that is, cis-di(thiocyanato)-N,N′-bis(2,2′-bipyridyl-4,4′-dicarboxylic acid)-ruthenium (II) (the concentration of N719: 3×10⁻⁴ mol/l). The substrate having the titanium oxide thin layer formed thereon was dipped in the resulting solution and allowed to stand for 20 hours under the temperature condition of 40° C. The substrate was then taken out from the solution, washed with ethanol and dried naturally in a dark place, whereby a semiconductor electrode having a dye adsorbed to titanium oxide was completed.

To the dye-adsorbed semiconductor electrode, 3,4-ethylenedioxythiophene (EDOT) was adsorbed in the following manner. In a solution (concentration of EDOT: 1.0 mol/l) prepared by dissolving EDOT in acetonitrile, the dye-adsorbed semiconductor electrode was dipped and then allowed to stand at room temperature for 5 minutes. After dipping, the semiconductor electrode was taken out from the solution, washed with acetonitrile and dried naturally in a dark place, whereby a semiconductor electrode 2 was completed.

A substrate for a counter electrode equal in shape and size to those of the substrate used for the semiconductor electrode was prepared by sputtering platinum on a transparent conductive glass (sputtered ITO glass, product of Nippon Sheet Glass).

As the electrolyte solution E, an iodine redox solution (iodine: 0.05 mol/l, lithium iodide: 0.1 mol/l, 2,3-dimethyl-imidazolium iodide: 0.5 mol/l, solvent: methoxyacetonitrile) was prepared.

A thermoplastic film (“HIMILAN 1702”, trade name; product of Dupont Mitsui Polychemical) having a size suited for the semiconductor electrode was prepared as Spacer S. As illustrated in FIG. 2, the semiconductor electrode 2 was placed opposite to the counter electrode CE via the spacer S and the substrate was heated to make these electrodes stick together. The electrolyte solution E was filled in a space formed by the spacer S, semiconductor electrode 2 and counter electrode CE by making use of capillary action. Any adjacent two of these members are sealed with an epoxy adhesive, whereby the dye sensitized solar cell was completed.

[Cell Characteristic Test 1]

A cell characteristic test was conducted in accordance with the below-described procedure under the below-described conditions and the short-circuit current density (unit: mA/cm²), open circuit voltage (unit: V) and photovoltaic conversion efficiency η of the dye sensitized solar cell obtained in Example 1 were measured.

The cell characteristics were evaluated by exposing the cell to an artificial sun light at one sun illumination and air mass of 1.5 by using a solar simulator (“XIL-05A50K”, trade name; product of Seric).

Current/Voltage characteristic of each dye sensitized solar cell was measured at room temperature (20° C.) by using a potentiostat (“BAS-100W”, product of BAS) and open circuit voltage Voc (unit: V), short-circuit current density Jsc (mA/cm²) and fill factor FF were determined. Based on them, a photovoltaic conversion efficiency η (unit: %) in the early stage after driving was started was determined.

As a result of the above-described measurement, it was found that short-circuit current density, open circuit voltage and photovoltaic conversion efficiency were 13.2 mA/cm², 0.62V and 4.62%, respectively.

### EXAMPLE 2

An acetonitrile solution of EDOT having a concentration of 5.0 ml/l was prepared. In a similar procedure under similar conditions to Example 1 except that the dipping time of the semiconductor electrode in the resulting solution was changed to 30 seconds, a dye sensitized solar cell was manufactured.

[Cell Characteristic Test 1]

Cell characteristic test was performed in a similar procedure under measuring conditions to those employed in Example 1 and short-circuit current density (unit: mA/cm²), open circuit voltage (unit: V), and photovoltaic conversion efficiency η of the dye sensitized solar cell obtained in Example 2 were measured.

As a result of the above-described measurement, it was found that the short-circuit current density, open circuit voltage and photovoltaic conversion efficiency were 14.0 mA/cm², 0.68V and 5.02%, respectively.

It has been confirmed from Examples 1 and 2 that when the concentration of EDOT is changed from 1.0 mol/l to 5.0 mol/l, sufficient open circuit voltage and photovoltaic conversion efficiency can be attained by changing the electrode dipping time to 30 seconds.

### EXAMPLE 3

An acetonitrile solution of EDOT having a concentration of 0.1 ml/l was prepared. In a similar procedure under similar conditions to Example 1 except that the dipping time of the semiconductor electrode in the resulting solution was changed to 60 minutes, a dye sensitized solar cell was manufactured.

[Cell Characteristic Test 1]

Cell characteristic test was performed in a similar procedure under similar measuring conditions to those employed in Example 1 and short-circuit current density (unit: mA/cm²), open circuit voltage (unit: V), and photovoltaic conversion efficiency η of the dye sensitized solar cell obtained in Example 3 were measured.

As a result of the above-described measurement, it was found that the short-circuit current density, open circuit voltage and photovoltaic conversion efficiency were 13.0 mA/cm², 0.65V and 4.89%, respectively.

It has been confirmed from Examples 1 and 3 that when the concentration of EDOT was changed from 1.0 mol/l to 0.1 mol/l, sufficient open circuit voltage and photovoltaic conversion efficiency can be attained by changing the dipping time of the electrode in the EDOT solution to 60 minutes.

It has been confirmed from Examples 1 to 3 that when the concentration of EDOT was changed from 0.1 mol/l to 5.0 mol/l, sufficient open circuit voltage and photovoltaic conversion efficiency can be attained by changing the dipping time of the electrode in the EDOT solution.

### EXAMPLE 4

Thiophene was used instead of EDOT and a solution of it in acetonitrile having a concentration of 1.0 ml/l was prepared. In a similar procedure under similar conditions to Example 1 except that the resulting thiophene solution was used, a dye sensitized solar cell was manufactured.

[Cell Characteristic Test 1]

Cell characteristic test was performed in a similar procedure under similar measuring conditions to those employed in Example 1 and short-circuit current density (unit: mA/cm²), open circuit voltage (unit: V), and photovoltaic conversion efficiency η of the dye sensitized solar cell obtained in Example 4 were measured.

As a result of the above-described measurement, it was found that the short-circuit current density, open circuit voltage and photovoltaic conversion efficiency were 13.2 mA/cm², 0.62V and 4.40%, respectively.

### EXAMPLE 5

The compound represented by the formula (3) was used instead of EDOT and a solution of it in acetonitrile having a concentration of 1.0 ml/l was prepared. In a similar procedure under similar conditions to those employed in Example 1 except for the use of the solution of the compound represented by the formula (3), a dye sensitized solar cell was manufactured.

[Cell Characteristic Test 1]

Cell characteristic test was performed in a similar procedure under similar measuring conditions to those employed in Example 1 and short-circuit current density (unit: mA/cm²), open circuit voltage (unit: V), and photovoltaic conversion efficiency η of the dye sensitized solar cell obtained in Example 5 were measured.

As a result of the above-described measurement, it was found that the short-circuit current density, open circuit voltage and photovoltaic conversion efficiency were 12.8 mA/cm², 0.63V and 4.32%, respectively.

### EXAMPLE 6

EDOT was replaced by a compound of the formula (4) in which substituents R₁ to R₄ each represents a hydrogen atom. A solution of this compound in acetonitrile having a concentration of 1.0 ml/l was prepared. In a similar procedure under similar conditions to Example 1 except for the use of the compound of the formula (4) in which substituents R₁ to R₄ each represents a hydrogen atom, a dye sensitized solar cell was fabricated.

s[Cell Characteristic Test 1]

Cell characteristic test was performed in a similar procedure under similar measuring conditions to those employed in Example 1 and short-circuit current density (unit: mA/cm²), open circuit voltage (unit: V), and photovoltaic conversion efficiency η of the dye sensitized solar cell obtained in Example 6 were measured.

As a result of the above-described measurement, it was found that the short-circuit current density, open circuit voltage and photovoltaic conversion efficiency were 13.0 mA/cm², 0.64V and 4.50%, respectively.

### EXAMPLE 7

EDOT was replaced by a compound of the formula (5) in which substituents R₁ and R₂ each represents a hydrogen atom was used. A solution of this compound in acetonitrile having a concentration of 1.0 ml/l was prepared. In a similar procedure under similar conditions to those employed in Example 1 except for the use of the compound of the formula (5) in which substituents R₁ and R₂ each represents a hydrogen atom, a dye sensitized solar cell was fabricated.

[Cell Characteristic Test 1]

Cell characteristic test was performed in a similar procedure under similar measuring conditions to those employed in Example 1 and short-circuit current density (unit: mA/cm²), open circuit voltage (unit: V), and photovoltaic conversion efficiency η of the dye sensitized solar cell obtained in Example 7 were measured.

As a result of the above-described measurement, it was found that the short-circuit current density, open circuit voltage and photovoltaic conversion efficiency were 12.5 mA/cm², 0.60V and 4.18%, respectively.

### COMPARATIVE EXAMPLE 1

In a similar procedure under similar conditions to Example 1 except that dipping treatment in an EDOT solution after the dye adsorption was omitted and, as the electrolyte solution E, an iodine redox solution (iodine: 0.05 mol/l, lithium iodide: 0.1 mol/l, 2,3-dimethyl-imidazolium iodide: 0.5 mol/l, solvent: methoxyacetonitrile) was used, a dye sensitized solar cell was obtained.

[Cell Characteristic Test 1]

Cell characteristic test was performed in a similar procedure under similar measuring conditions to those employed in Example 1 and short-circuit current density (unit: mA/cm²), open circuit voltage (unit: V), and photovoltaic conversion efficiency η of the dye sensitized solar cell manufactured in Comparative Example 1 were measured.

As a result of the above-described measurement, it was found that the short-circuit current density, open circuit voltage and photovoltaic conversion efficiency were 10.5 mA/cm², 0.56V and 3.50%, respectively.

Comparison between the results obtained in Examples 1 to 7 and Comparative Example 1 has revealed that the open circuit voltage and photovoltaic conversion efficiency of the dye sensitized solar cells in Examples 1 to 7 are superior to those of the dye sensitized solar cell in Comparative Example 1. The advantage of the present invention can be confirmed by the test results of Examples 1 to 7.

The above-described results of Example 1 to Example 7 and Comparative Example 1 are shown in Table 1.

TABLE 1

| | | Jsc | Voc | |
|---|---|---|---|---|
| | Conditions | (mA/cm²) | (V) | η (%) |
| Ex. 1 | Dipping in 1.0M EDOT | 13.2 | 0.62 | 4.67 |
| | solution for 5 min. | | | |
| Ex. 2 | Dipping in 5.0M EDOT | 14.0 | 0.68 | 5.02 |
| | solution for 30 sec. | | | |
| Ex. 3 | Dipping in 0.1M EDOT | 13.0 | 0.65 | 4.89 |
| | solution for 60 min. | | | |
| Ex. 4 | Dipping in 1.0M thiophene | 13.2 | 0.62 | 4.40 |
| | solution for 5 min. | | | |
| Ex. 5 | Dipping in 1.0M solution of | 12.8 | 0.63 | 4.32 |
| | Formula (3) for 5 min. | | | |
| Ex. 6 | Dipping in 1.0M solution of | 13.0 | 0.64 | 4.50 |
| | Formula (4) for 5 min. | | | |
| Ex. 7 | Dipping in 1.0M solution of | 12.5 | 0.60 | 4.18 |
| | Formula (5) for 5 min. | | | |
| Comp. | No dipping treatment | 10.5 | 0.56 | 3.50 |
| Ex. 1 | | | | |

[Cell Characteristic Test 2]

Each of the dye sensitized solar cells manufactured in Example 1 and Examples 4 to 7 was stored at room temperature in a dark place in open circuit mode. Current/Voltage characteristics of each dye sensitized solar cell after 12 hours and 24 hours were measured and open circuit voltage Voc (unit: V), short-circuit current density Jsc (mA/cm²) and fill factor FF were determined. Based on them, a photovoltaic conversion efficiency η (unit: %) in the early stage after driving was started was determined.

The cell characteristic test 2 of the dye sensitized solar cell manufactured in Example 1 was performed. As a result, it was found that the short-circuit current density after 12 hours was 13.3 mA/cm², while the short-circuit current density after 24 hours was 12.8 mA/cm².

The cell characteristic test 2 of the dye sensitized solar cell fabricated in Example 4 was performed. As a result, it was found that the short-circuit current density after 12 hours was 12.9 mA/cm², while the short-circuit current density after 24 hours was 12.6 mA/cm².

The cell characteristic test 2 of the dye sensitized solar cell manufactured in Example 5 was performed. As a result, it was found that the short-circuit current density after 12 hours was 12.5 mA/cm², while the short-circuit current density after 24 hours was 12.3 mA/cm².

The cell characteristic test 2 of the dye sensitized solar cell manufactured in Example 6 was performed. As a result, it was found that the short-circuit current density after 12 hours was 12.8 mA/cm², while the short-circuit current density after 24 hours was 12.5 mA/cm².

The cell characteristic test 2 of the dye sensitized solar cell manufactured in Example 7 was performed. As a result, it was found that the short-circuit current density after 12 hours was 12.3 mA/cm², while the short-circuit current density after 24 hours was 12.3 mA/cm².

### COMPARATIVE EXAMPLE 2

In similar procedure under similar conditions to those employed in Example 1 except that dipping treatment in an EDOT solution after the dye adsorption was omitted and as the electrolyte solution E, an iodine redox solution (iodine: 0.05 mol/l, lithium iodide: 0.1 mol/l, 2,3-dimethyl-imidazolium iodide: 0.5 mol/l, EDOT: 0.6 mol/l, solvent: methoxyacetonitrile) was used, a dye sensitized solar cell was obtained.

The cell characteristic test 2 of the dye sensitized solar cell manufactured in Comparative Example 2 was performed. As a result, it was found that the short-circuit current density after 12 hours was 9.6 mA/cm², while the short-circuit current density after 24 hours was 8.9 mA/cm².

### COMPARATIVE EXAMPLE 3

In a similar procedure under similar conditions to those employed in Example 1 except that the dipping treatment in an EDOT solution after the dye adsorption was omitted, and as the electrolyte solution E, an iodine redox solution (iodine: 0.05 mol/l, lithium iodide: 0.1 mol/l, 2,3-dimethyl-imidazolium iodide: 0.5 mol/l, 4-tert-butylpyridine (TBP): 0.6 mol/l, solvent: methoxyacetonitrile) was used, a dye sensitized solar cell was obtained.

The cell characteristic test 2 of the dye sensitized solar cell manufactured in Comparative Example 3 was performed. As a result, it was found that the short-circuit current density after 12 hours was 10.4 mA/cm², while the short-circuit current density after that after 24 hours was 9.0 mA/cm².

From the results of the cell characteristic test 2 using the dye sensitized solar cells obtained in Example 1, Examples 4 to 7, and Comparative Examples 2 to 3, it has been confirmed that a reduction in the short-circuit current density can be prevented greatly in the dye sensitized solar cells having a thiophene-ring-containing organic compound adsorbed to the semiconductor electrode, compared with the dye sensitized solar cell using an electrolyte solution having EDOT or TBP mixed therein as an additive.

The results of the cell characteristic test 2 of the dye sensitized solar cells manufactured in Example 1, Examples 4 to 7, and Comparative Examples 2 to 3 are shown in Table 2. The results of Example 1 and Comparative Example 3, typical of these Examples and Comparative Examples, are shown as a graph in FIG. 4.

TABLE 2

| | | | Jsc | Jsc |
|---|---|---|---|---|
| | | Jsc | After | After |
| | | Initial | 12 | 24 |
| | | stage | hours | hours |
| | Conditions | (mA/cm²) | (mA/cm²) | (mA/cm²) |
| Ex. 1 | Dipping in 1.0M EDOT | 13.2 | 13.3 | 12.8 |
| | solution for 5 min. | | | |
| EX. 4 | Dipping in 1.0M thiophene | 13.2 | 12.9 | 12.6 |
| | solution for 5 min. | | | |
| Ex. 5 | Dipping in 1.0M solution | 12.8 | 12.5 | 12.3 |
| | of Formula (3) for 5 min. | | | |
| Ex. 6 | Dipping in 1.0M solution | 13.0 | 12.8 | 12.5 |
| | of Formula (4) for 5 min. | | | |
| Ex. 7 | Dipping in 1.0M solution | 12.5 | 12.3 | 12.3 |
| | of Formula (5) for 5 min. | | | |
| Comp. | Electrolyte solution | 11.1 | 9.6 | 8.9 |
| Ex. 2 | containing EDOT | | | |
| Comp. | Electrolyte solution | 11.9 | 10.4 | 9.0 |
| Ex. 3 | containing TBP | | | |

From the results of Table 2, it has been confirmed that in the dye sensitized solar cells manufactured by bringing a thiophene-ring-containing organic compound into adsorption on a semiconductor electrode, a time-dependent decrease in short-circuit current density is very small compared with that of the dye sensitized solar cells having an electrolyte solution containing an additive therein (Comparative Examples 2 and 3).

What is claimed is:

1. A semiconductor electrode comprising a substrate having optical transparency, a transparent conductive layer provided on a photo-receptive surface of the substrate, and a porous semiconductor made of a metal oxide provided on the transparent conductive layer,
wherein the porous semiconductor has at least dye and a thiophene-ring-containing organic compound adsorbed thereon.

2. The semiconductor electrode according to claim 1, wherein the thiophene-ring-containing compound is represented by the following formula (1): 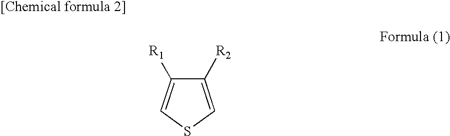
(in the formula (1), R₁ and R₂ may be the same or different, and each represents a characteristic group selected from the class consisting of a hydrogen atom, hydrocarbon groups having from 1 to 20 carbon atoms, and alkoxy groups having from 1 to 20 carbon atoms).

3. The semiconductor electrode according to claim 1, wherein the thiophene-ring-containing compound is composed of at least one compound selected from the group consisting of compounds represented by the following formulas (2) to (5):

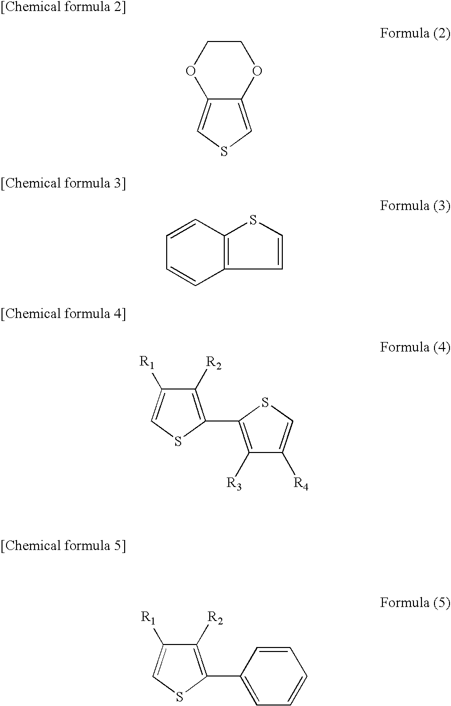

4. The semiconductor electrode according to claim 1, wherein at least one of the compounds represented by the formulas (1) to (5) is adsorbed onto the surface of the porous semiconductor by dipping in a solution having the compound dissolved in an organic solvent.

5. The semiconductor electrode according to any one of claims 1 to 3, wherein at least one of the compounds represented by the formula (1) to (5) is adsorbed to the surface of the porous semiconductor by evaporation.

6. The semiconductor electrode according to claim 1, wherein the thiophene-ring-containing organic compound has a molecular weight of 8000 or less.

7. A dye sensitized solar cell comprising a semiconductor electrode as claimed in claim 1 and a counter electrode thereof, wherein the semiconductor electrode and the counter electrode are placed opposite to each other via an electrolyte.

8. The dye sensitized solar cell according to claim 7, wherein the thiophene-ring-containing organic compound contained in the electrolyte has a concentration of 1 mmol/l or less.

9. The dye sensitized solar cell comprising a glass substrate having a concave channel formed therein, an interconnection composed mainly of a metal filled in the concave channel of the glass substrate, a transparent conductive layer formed so as to coat surfaces of the glass substrate and the interconnect, and a metal oxide layer formed on the surface of the transparent conductive layer,
wherein the metal oxide layer has a dye and a thiophene-ring-containing organic compound adsorbed thereon.

10. The dye sensitized solar cell according to claim 9, wherein the thiophene-ring-containing compound is represented by the following formula (1): 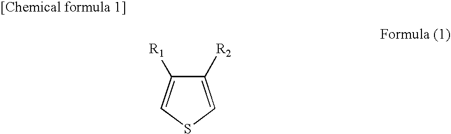
(in the formula (1), R₁ and R₂ may be the same or different and each represents a characteristic group selected from the class consisting of a hydrogen atom, hydrocarbon groups having from 1 to 20 carbon atoms, and alkoxy groups having from 1 to 20 carbon atoms).

11. The dye sensitized solar cell according to claim 9, wherein the thiophene-ring-containing compound is composed of at least one compound selected from the group consisting of compounds represented by the following formulas (2) to (5):

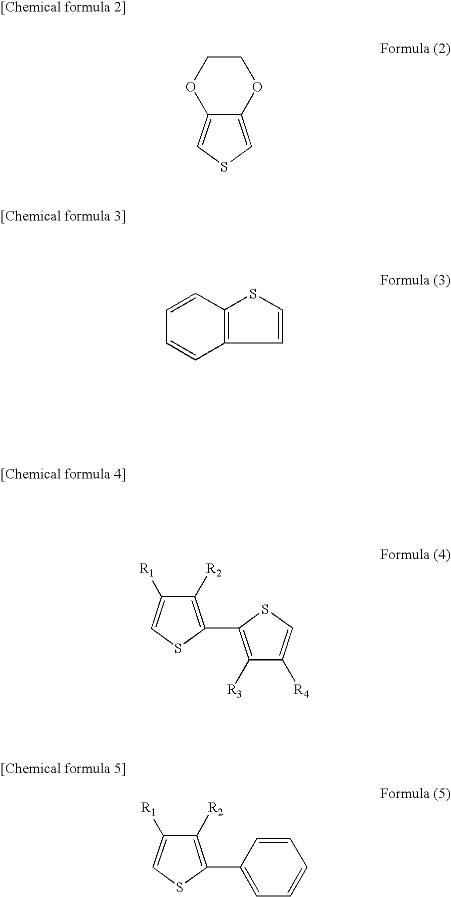

12. A manufacturing method of a semiconductor electrode comprising the steps of:
forming a transparent conductive layer on a photo-receptive surface of a substrate having optical transparency;
forming a porous semiconductor made of a metal oxide on the transparent conductive;
bringing a dye into adsorpition onto a surface of the porous semiconductor; and
bringing a thiophene-ring-containing compound into adsorption onto a portion missing the dye adsorption in the surface of the porous semiconductor.

13. The manufacturing method of the semiconductor electrode according to claim 12, wherein the step of the adsorption of the thiophene-ring-containing compound is carried out by dipping the substrate having the porous semiconductor formed thereon into a solution having the organic compound dissolved therein, or coating the solution onto the substrate; or allowing the substrate to stand in a container filled with the vapor of the thiophene-ring-containing compound.

14. The manufacturing method of the semiconductor electrode according to claim 12, wherein the substrate having the porous semiconductor formed thereon is dipped in a solution obtained by dissolving at least one of compounds represented by the formulas (1) to (5): 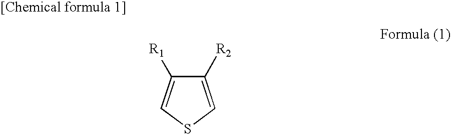
(in the formula (1), R₁ and R₂ may be the same or different and each represents a characteristic group selected from the class consisting of a hydrogen atom, hydrocarbon groups having from 1 to 20 carbon atoms, and alkoxy groups having from 1 to 20 carbon atoms). 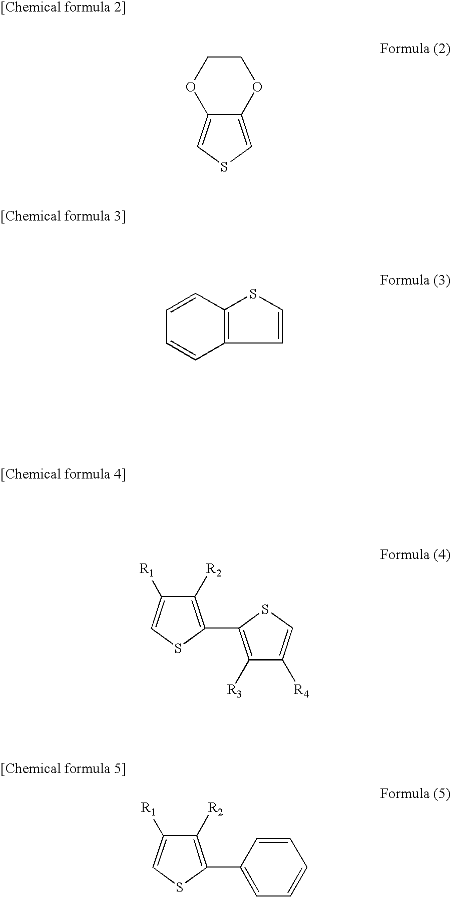
in an organic solvent to adsorb the compound to the surface of the porous semiconductor.

15. The manufacturing method of the semiconductor electrode according to claim 13, wherein the concentration of the thiophene-ring-containing compound in the solution is from 0.01 to 1 mol/l.

16. The manufacturing method of the semiconductor electrode according to claim 12, further comprising a step of forming an auxiliary electrode interconnection on the surface of the substrate having optical transparency, and forming the transparent conductive layer on the surface on which the auxiliary electrode interconnection has been formed.

17. A manufacturing method of a dye sensitized solar cell, which comprises the steps of:
bringing a thiophene-ring-containing compound into adsorption onto a portion missing dye adsorption in a surface of a porous semiconductor in a semiconductor electrode, which comprises a substrate having optical transparency, a transparent conductive layer on a photo-receptive surface of the substrate, the porous semiconductor made of a metal oxide on the transparent conductive layer, a dye coating adsorbed onto the surface of the porous semiconductor;
placing the semiconductor electrode and a counter electrode via a spacer so that their conductive surfaces face to each other;
filling an electrolyte between the semiconductor electrode and the counter electrode; and
sealing the semiconductor electrode, counter electrode and spacer for integration.
